(19) United States
(12) Patent Application Publication
(10) Pub. No.: US 2022/0302201 A1
(43) Pub. Date: Sep. 22, 2022

(54) STACKED LUMINESCENT DEVICE AND METHOD OF MANUFACTURING THE SAME

(71) Applicant: Hongyi Optical Co., Ltd., Taipei City (TW)

(72) Inventors: Yao-Tang Chang, New Taipei City (TW); Tzu Yu Lin, Taoyuan City (TW)

(73) Assignee: Hongyi Optical Co., Ltd., Taipei City (TW)

(21) Appl. No.: 17/697,946

(22) Filed: Mar. 18, 2022

Related U.S. Application Data
(60) Provisional application No. 63/162,563, filed on Mar. 18, 2021.

(51) Int. Cl. H01L 27/15; H01L 33/50; H01L 33/62

(52) U.S. Cl. CPC H01L 27/15; H01L 33/50; H01L 33/62; H01L 2933/0041; H01L 2933/0066

(57) ABSTRACT

Provided is a stacked luminescent device including a plurality of electroluminescent devices and a plurality of conductive lines. The electroluminescent devices are vertically stacked with each other to form a staircase structure on a staircase region. Each electroluminescent device includes a substrate, an encapsulation layer, and a quantum dot light-emitting diode (QLED) device sandwiched between the substrate and the encapsulation layer. The conductive lines are respectively connected to the QLED devices in the electroluminescence devices along the staircase structure. A method of manufacturing the stacked luminescent device is also provided.

### CROSS-REFERENCE TO RELATED APPLICATIONS

This application claims the priority benefits of U.S. provisional application Ser. No. 63/162,563 filed on Mar. 18, 2021. The entirety of each of the above-mentioned patent applications is hereby incorporated by reference herein and made a part of this specification.

### BACKGROUND OF THE INVENTION

### Field of the Invention

The present invention relates to a stacked luminescent device and a method of manufacturing the same.

### Description of Related Art

Since Edison invented the light bulb, with the advancement of technology, the light source used by humans has been developed from the light bulb to solid-state lighting (SSL) such as a light emitting diode (LED). The LED not only has the high-brightness output, but also has the advantages of power saving, low-voltage driving, and no mercury. Therefore, the LED has been widely used in the fields of displays and lighting.

Quantum dots (QDs) have the good luminescence quantum efficiency and can emit light by means of photoluminescence (PL) or electroluminescence (EL). Therefore, the combination of QDs with inorganic light-emitting diodes or the fabrication of devices with structures similar to organic light-emitting diodes is considered to have good development potential.

### SUMMARY OF THE INVENTION

The present invention provides a stacked luminescent device including a plurality of electroluminescent devices and a plurality of conductive lines. The electroluminescent devices are vertically stacked with each other to form a staircase structure on a staircase region. Each electroluminescent device includes a substrate, an encapsulation layer, and a quantum dot light-emitting diode (QLED) device sandwiched between the substrate and the encapsulation layer. The plurality of conductive lines are respectively connected to the plurality of QLED devices in the plurality of electroluminescence devices along the staircase structure.

In one embodiment of the present invention, the plurality of electroluminescent devices include: a first electroluminescent device having a red quantum dot film; a second electroluminescent device having a green quantum dot film; and a third electroluminescent device having a blue quantum dot film, wherein the second electroluminescent device is disposed between the first electroluminescent device and the third electroluminescent device.

In one embodiment of the present invention, each electroluminescent device has a bidirectional emission light toward above and below the electroluminescent device.

In one embodiment of the present invention, the stacked luminescent device further includes: a plurality of gold fingers disposed on an edge of a bottommost substrate, wherein the plurality of gold fingers are respectively electrically connected to the plurality of electroluminescent devices by the plurality of conductive lines.

In one embodiment of the present invention, one of the plurality of electroluminescent devices includes: a first electrode layer and a second electrode layer; a light emitting layer disposed between the first electrode layer and the second electrode layer; a hole transport layer disposed between the first electrode layer and the light emitting layer; and an electron transport layer disposed between the second electrode layer and the light emitting layer.

In one embodiment of the present invention, the first electrode layer includes an anode or a cathode, the second electrode layer includes a cathode or an anode, and the light emitting layer includes a quantum dot layer.

The present invention provides a method of manufacturing a stacked luminescent device including: forming a plurality of electroluminescent devices by using a transfer printing process, wherein each electroluminescent device comprises a substrate, an encapsulation layer, and a quantum dot light-emitting diode (QLED) device sandwiched between the substrate and the encapsulation layer; stacking the plurality of electroluminescent devices on each other, wherein end portions of the plurality of encapsulation layers and end portions of the plurality of substrates in the plurality of electroluminescent devices form a staircase structure; and forming a plurality of conductive lines respectively connected to the plurality of QLED devices in the plurality of electroluminescence devices along the staircase structure.

In one embodiment of the present invention, the transfer printing process includes a flexographic printing process.

In one embodiment of the present invention, the forming the plurality of conductive lines includes: a screen printing method, a transfer printing method, an evaporation method, a conductive carbon glue sticking method, a conductive tape sticking method, or a combination thereof.

In one embodiment of the present invention, the plurality of electroluminescent devices include: a first electroluminescent device having a red quantum dot film; a second electroluminescent device having a green quantum dot film; and a third electroluminescent device having a blue quantum dot film, wherein the second electroluminescent device is disposed between the first electroluminescent device and the third electroluminescent device.

Based on above, in the embodiment of the present invention, a plurality of electroluminescent devices are stacked on each other. In this case, the red quantum dot film, the green quantum dot film, and the blue quantum dot film in the electroluminescent devices are vertically stacked and overlapped with each other, so that the red emission light, the green emission light, and the blue emission light are mixed uniformly to form a white light, or the proportion of different color lights can be adjusted to generate various mixed color lights, thereby achieving the effect of colored light sheets.

In addition, the red quantum dot film, the green quantum dot film, and the blue quantum dot film in the electroluminescent devices can be formed by a transfer printing process. In such embodiment, the manufacturing method is able to achieve rapid fabrication and fabricate electroluminescent device with a large area and any shape. In this case, the method of manufacturing the stacked luminescent device of the present invention is beneficial to mass production in industry, and is able to greatly reduce production costs and increase production capacity, thereby achieving commercial utilization and enhancing commercial competitiveness.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a stacked luminescent device according to an embodiment of the present invention.

FIG. 2 is a schematic cross-sectional view of a stacked luminescent device according to a first embodiment of the present invention.

FIG. 3 is a schematic perspective view of a stacked luminescent device according to an embodiment of the present invention.

FIG. 4 is a schematic cross-sectional view of an electroluminescent device according to an embodiment of the present invention.

FIG. 5 is a schematic cross-sectional view of a stacked luminescent device according to a second embodiment of the present invention.

FIG. 6 is a block diagram of a method of manufacturing a stacked luminescent device according to an embodiment of the present invention.

FIG. 7 is a schematic cross-sectional view of a stacked luminescent device according to a third embodiment of the present invention.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the Figures The spatially relative terms are intended to encompass different orientations of the device in use or operation in addition to the orientation depicted in the Figures The apparatus may be otherwise oriented (rotated 90 degrees or at other orientations) and the spatially relative descriptors used herein may likewise be interpreted accordingly.

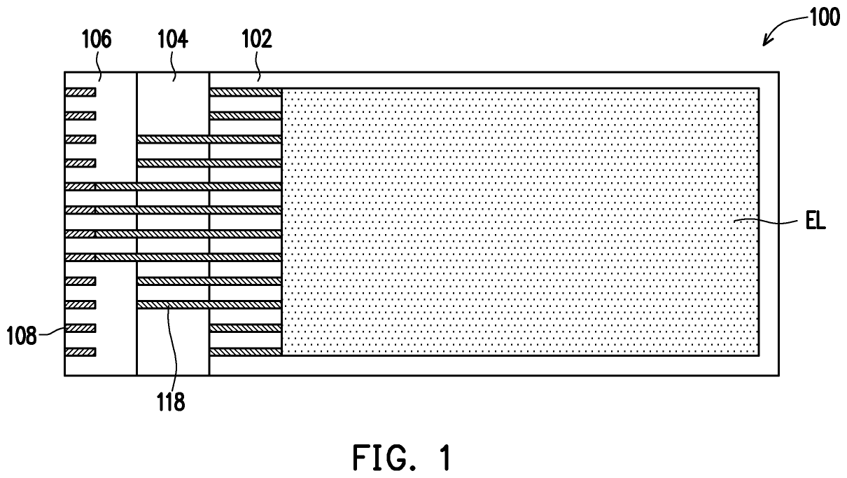

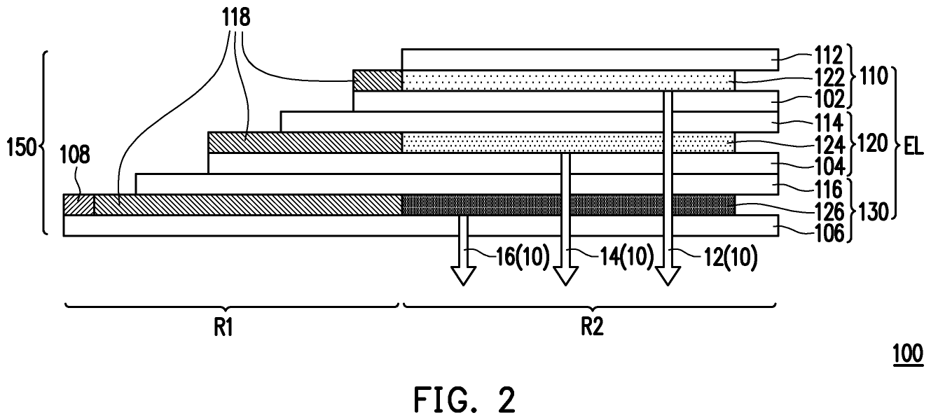

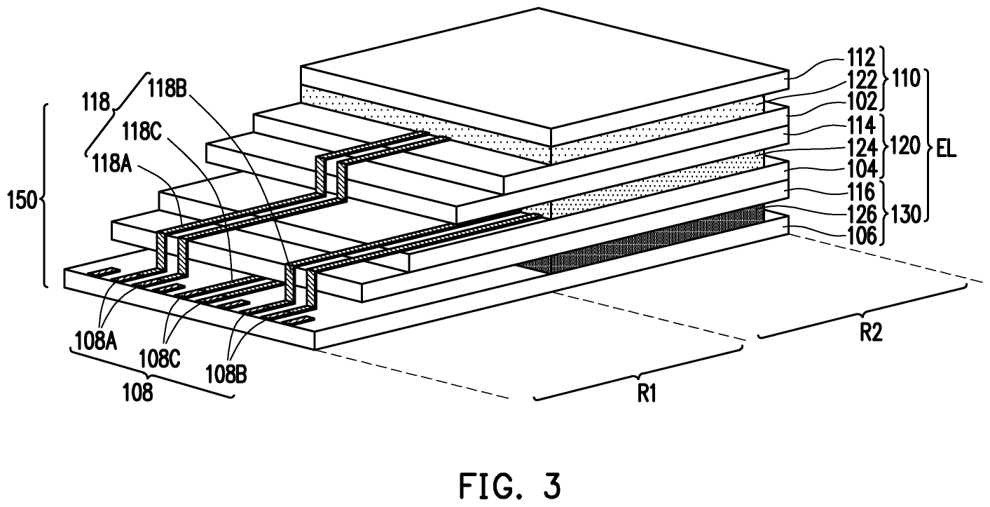

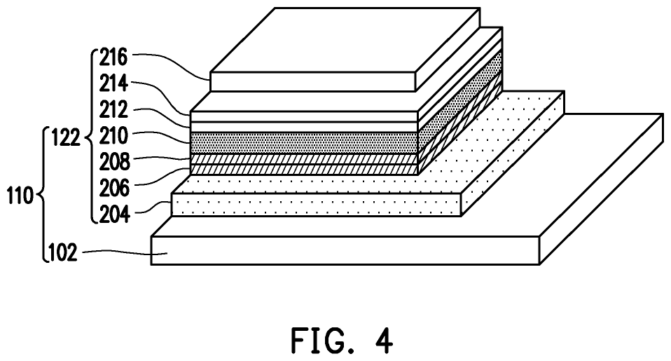

FIG. 1 is a schematic top view of a stacked luminescent device according to an embodiment of the present invention. FIG. 2 is a schematic cross-sectional view of a stacked luminescent device according to a first embodiment of the present invention. FIG. 3 is a schematic perspective view of a stacked luminescent device according to an embodiment of the present invention. FIG. 4 is a schematic cross-sectional view of an electroluminescent device according to an embodiment of the present invention.

Referring to FIG. 1 and FIG. 2, in an embodiment of the present invention, a stacked luminescent device 100 is provided to include: a plurality of electroluminescent devices EL vertically stacked with each other. Specifically, the electroluminescent devices EL may include: a first electroluminescent device 110, a second electroluminescent device 120, and a third electroluminescent device 130. In one embodiment, the first electroluminescent device 110 includes a substrate 102, an encapsulation layer 112, and a quantum dot light-emitting diode (QLED) device 122 sandwiched between the substrate 102 and the encapsulation layer 112. The second electroluminescent device 120 may include a substrate 104, an encapsulation layer 114, and a QLED device 124 sandwiched between the substrate 104 and the encapsulation layer 114. The third electroluminescent device 130 may include a substrate 106, an encapsulation layer 116, and a QLED device 126 sandwiched between the substrate 106 and the encapsulation layer 116.

In one embodiment, a material of the substrates 102, 104, and 106 may be glass, quartz, organic polymers, plastic, flexible plastic, or other suitable transparent materials, but the invention is not limited thereto.

In one embodiment, a material of the encapsulation layers 112, 114, and 116 includes a polymer coating layer such as diamond-like carbon thin film, silicon oxide, titanium oxide, aluminum oxide, silicon nitride, glass, polyethylene terephthalate (PET), Epoxy, acryl or the like, or similar gas barrier material, so as to effectively block the external environmental factors such as moisture, oxygen, volatile substances and so on.

In one embodiment, the first electroluminescent device 110, the second electroluminescent device 120, and the third electroluminescent device 130 have quantum dot films of different colors. For example, the first electroluminescent device 110 may have a red quantum dot film. The second electroluminescent device 120 may have a green quantum dot film. The third electroluminescent device 130 may have a blue quantum dot film. In such embodiment, as shown in FIG. 2, the first electroluminescent device 110 is disposed on the third electroluminescent device 130, and the second electroluminescent device 120 is disposed between the first electroluminescent device 110 and the third electroluminescent device 130.

In one embodiment, each electroluminescent device EL includes a quantum dot light-emitting diode (QLED) device. Specifically, taking the first electroluminescent device 110 as an example, as shown in FIG. 4, the first electroluminescent device 110 may include the substrate 102 and the QLED device 122 (for the sake of clarity, the gas barrier layer is omitted here). The QLED device 122 includes, from bottom to top, a first electrode layer 204, a hole injection layer 206, a hole transport layer 208, a light emitting layer 210, an electron transport layer 212, an electron injection layer 214, and a second electrode layer 216. In this case, the first electrode layer 204 may be used as an anode, and the second electrode layer 216 may be used as a cathode. The light emitting layer 210 may be a quantum dot light emitting layer having a plurality of quantum dots. In the QLED device 122, the holes from the first electrode layer 204 may be transmitted to the quantum dot light emitting layer 210 through the hole injection layer 206 and the hole transport layer 208, while the electrons from the second electrode layer 216 may be transmitted to the quantum dot light emitting layer 210 through the electron injection layer 214 and the electron transport layer 212. In this case, the transmitted electrons and holes are recombined in the quantum dot light emitting layer 210 to form excitons, thereby emitting light.

In alternative embodiments, the first electroluminescent device 110 may include sequentially from bottom to top: the first electrode layer 204, the electron injection layer 206, the electron transport layer 208, the light emitting layer 210, the hole transport layer 212, the hole injection layer 214, and the second Electrode layer 216. In this case, the first electrode layer 204 may be used as a cathode, and the second electrode layer 216 may be used as an anode.

In one embodiment, materials of the first electrode layer 204 and the second electrode layer 216 may each include a conductive material, such as indium tin oxide (ITO), aluminum (Al), silver (Ag), chromium (Cr), copper (Cu)), nickel (Ni), titanium (Ti), molybdenum (Mo), magnesium (Mg), platinum (Pt), gold (Au), or a combination thereof. In the embodiment, the first electrode layer 204 and the second electrode layer 216 may include the same conductive material or different conductive materials. Taking the stacked luminescent device 100 of FIG. 2 as an example to illustrate, since an emission light 10 of the first electroluminescent device 110 needs to penetrate the first electrode layers and the second electrode layers of the second and third electroluminescent devices 120 and 130, the first electrode layers and the second electrode layers of the second and third electroluminescent devices 120 and 130 both are transparent electrodes such as indium tin oxide (ITO) or extremely thin metal electrodes.

In one embodiment, a material of the hole injection layer 206 may include an inorganic material and an organic material. The inorganic material may include, but is not limited to, suitable materials such as NiO, WO₃, MoO₃, etc. The organic material may include, but is not limited to, poly(3,4-ethylenedioxythiophene) polystyrene sulfonate (PEDOT:PSS) or other suitable materials. A material of the hole transport layer 208 may include an inorganic material and an organic material. The inorganic material may include, but is not limited to NiO; while the organic material may include, but is not limited to, TFB (Poly(9,9-dioctylfluorene-alt-N-(4-sec-butylphenyl)-diphenylamine)), pTPD (Poly(N,N′-bis-4-butylphenyl-N,N′-bisphenyl)benzidine) or other suitable materials. A material of the electron transport layer 212 may include, but is not limited to, suitable inorganic materials such as ZnO and ZnMgO. A material of the electron injection layer 214 may include, but is not limited to, suitable inorganic materials such as ZnO and LiF. In other embodiments, the electron transport layer 212 and the electron injection layer 214 may be combined into a single ZnO layer to achieve the functions of electron transport and electron injection simultaneously.

It should be noted that, in the embodiment, the light emitting layer 210 includes a quantum dot layer (film). The quantum dot layer may include a plurality of quantum dots uniformly distributed in a matrix material. Optionally, the quantum dots may also be not added into the matrix material, thereby forming a film individually. The quantum dots are tiny semiconductor nanostructures that are invisible to the naked eye. When the quantum dots are stimulated by external energy, such as light or electricity, the quantum dots emit light with wavelengths in the visible range and with pure color. The color of light may be determined by the composition and particle size of the quantum dots. That is, a single kind of quantum dots may emit a single color of light. For example, the light emitting layer in first electroluminescent device 110 may have the red quantum dots, the light emitting layer in second electroluminescent device 120 may have the green quantum dots, and the light emitting layer in third electroluminescent device 130 may have the blue quantum dots. When the different quantum dot layers respectively include quantum dots of different colors, the light of different colors may be mixed to form a white light, thereby applying in a light source or a backlight module of a display.

In some embodiments, the quantum dots include a core, a core-shell, a core-alloy layer-shell, an alloy-shell, a core (alloy)-multilayer shell, or a combination thereof. The particle size or dimension of the quantum dots may be adjusted according to needs (e.g., to emit visible lights of different colors), and the invention is not limited thereto. In some embodiments, the matrix material may include a resin material, such as acrylic resin, epoxy, silicone, or a combination thereof.

In one embodiment, said “core” may be, for example, at least one selected from the group consisting of CdS, CdSe, CdTe, ZnS, ZnSe, ZnTe, HgS, HgSe, HgTe, GaN, GaP, GaAs, InP, InAs, InSb, AlN, AlP, AlAs, AlSb, SiC, Fe, Pt, Ni, Co, Al, Ag, Au, Cu, FePt, Si, Ge, PbS, PbSe, PbTe and alloys thereof. In one embodiment, said “shell” is, for example, at least one selected from the group consisting of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe and alloys thereof. Said core or said shell may be selected according to different needs, and the invention is not limited thereto.

It should be noted that, as shown in FIG. 2 and FIG. 3, the electroluminescent devices EL are vertically stacked on each other to form a staircase structure 150 on a staircase region R1. Specifically, the electroluminescent devices EL may include a staircase region R1 and a light emitting region R2 adjacent to each other. In one embodiment, the staircase region R1 is used for electrical routing, and the light emitting region R2 is used for emitting light.

In one embodiment, as shown in FIG. 2, the emission light 10 is emitted downward by using the bottom substrate 106 as a light-emitting surface. Specifically, the first electroluminescent device 110 has a first emission light 12 (e.g., red light), and the first emission light 12 passes through the second electroluminescent device 120 and the third electroluminescent device 130 and is emitted toward the bottom substrate 106. Similarly, the second electroluminescent device 120 has a second emission light 14 (e.g., green light), and the second emission light 14 passes through the third electroluminescent device 130 and is emitted toward the bottom substrate 106. Specifically, the second emission light 14 may have upward and/or downward light, the upward light would reach the first electroluminescent device 110 and then be reflected by the second electrode layer 216 (as shown in FIG. 4) composed of the reflective metal, and then be emitted toward the bottom substrate 106. Therefore, the second emission light 14 is mainly emitted from the bottom substrate 106. Further, the third electroluminescent device 130 has a third emission light 16 (e.g., blue light), and the third emission light 16 is also emitted toward the bottom substrate 106. Specifically, the third emission light 16 may have upward and/or downward light. The upward light would pass through the second electroluminescent device 120 composed of fully transparent devices. Next, the upward light would reach the first electroluminescent device 110 and then be reflected by the second electrode layer 216 (as shown in FIG. 4) composed of the reflective metal, and then be emitted toward the bottom substrate 106. Therefore, the third emission light 16 is mainly emitted from the bottom substrate 106.

In one embodiment, the first emission light 12, the second emission light 14, and the third emission light 16 may have different wavelengths. In the embodiment, the wavelength of the first emission light 12 is greater than the wavelength of the second emission light 14, and the wavelength of the second emission light 14 is greater than the wavelength of the third emission light 16. It should be noted that since the short-wavelength light has higher energy, when the short-wavelength light passes through the quantum dots with longer wavelengths, the said short-wavelength light would be absorbed by the quantum dots, thereby emitting the longer-wavelength light. In this case, in the embodiment, the electroluminescent devices (i.e., the quantum dot layers) may be arranged in order of wavelength, so that the long-wavelength light passes through the short-wavelength quantum dot layer, thereby avoiding the emission light being absorbed and maintaining the luminous efficacy.

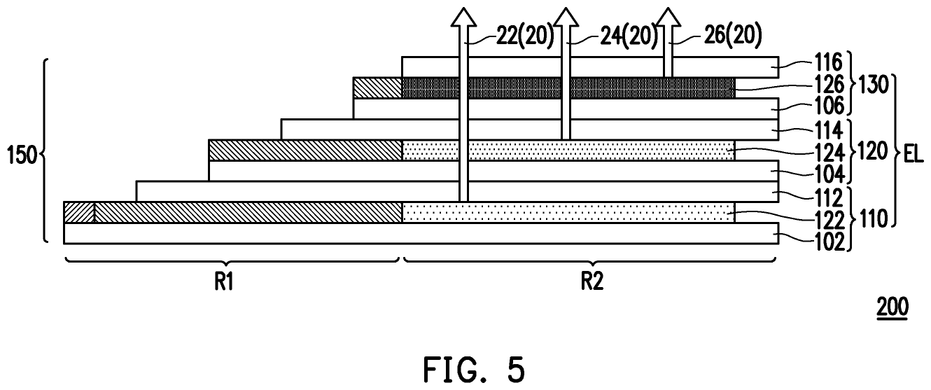

Although the emission light 10 illustrated in FIG. 2 is emitted downward, the present invention is not limited thereto. In other embodiments, as shown in FIG. 5, the emission light 20 of the stacked luminescent device 200 may also be emitted upward. In such embodiment, the third electroluminescent device 130 is disposed on the first electroluminescent device 110, and the second electroluminescent device 120 is disposed between the first electroluminescent device 110 and the third electroluminescent device 130. Specifically, the first electroluminescent device 110 has a first emission light 22 (e.g., red light), and the first emission light 22 passes through the second electroluminescent device 120 and the third electroluminescent device 130 and is emitted toward the top encapsulation layer 116. Similarly, the second electroluminescent device 120 has a second emitting light 24 (e.g., green light), and the second emitting light 24 passes through the third electroluminescent device 130 and is emitted toward the top encapsulation layer 116. Specifically, the second emission light 24 may have upward and/or downward light, the downward light would reach the first electroluminescent device 110 and then be reflected by the first electrode layer 204 (shown in FIG. 4) composed of reflective metal, and then be emitted toward the top encapsulation layer 116. Therefore, the second emission light 24 is mainly emitted from the top encapsulation layer 116. Further, the third electroluminescent device 130 has a third emission light 26 (e.g., blue light), and the third emission light 26 is also emitted toward the top encapsulation layer 116. Specifically, the third emission light 26 may have upward and/or downward light. The downward light would pass through the second electroluminescent device 120 composed of fully transparent devices. Next, the downward light would reach the first electroluminescent device 110 and then be reflected by the first electrode layer 204 (as shown in FIG. 4) composed of the reflective metal, and then be emitted toward the top encapsulation layer 116. Therefore, the third emission light 26 is mainly emitted from the top encapsulation layer 116.

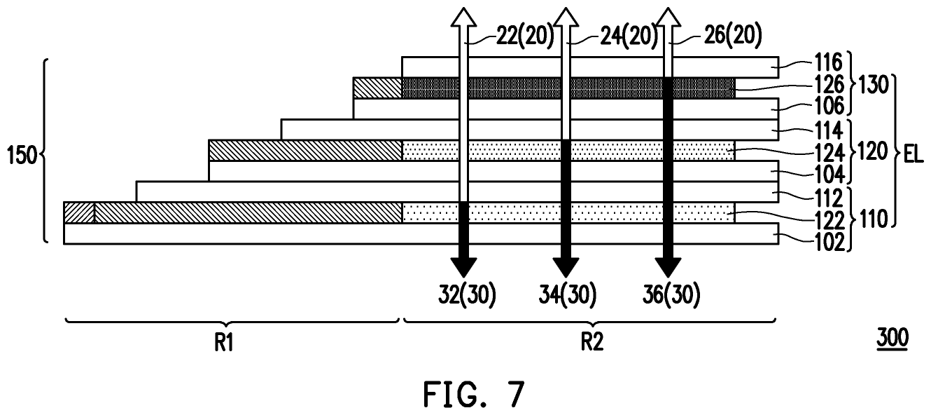

In alternative embodiments, each electroluminescent device EL of the stacked luminescent device 300 has bidirectional emission lights 20 and 30 toward above and below the electroluminescent device EL. Specifically, as shown in FIG. 7, the first electroluminescent device 110 has first emission lights 22 and 32 (e.g., red lights), the first emission light 22 is emitted upward, and the first emission light 32 is emitted downward. Similarly, the second electroluminescent device 120 has second emitting lights 24 and 34 (e.g., green lights), the second emitting light 24 is emitted upward, and the second emission light 34 is emitted downward. Further, the third electroluminescent device 130 has third emitting lights 26 and 36 (e.g., blue lights), the third emitting light 26 is emitted upward, and the third emission light 36 is emitted downward. In this case, the stacked luminescent device 300 may be regarded as a transparent light sheet with a bidirectional emission light. That is, only when the first electroluminescent device 110, the second electroluminescent device 120, and the third electroluminescent device 130 are all transparent devices (i.e., the electrode layers 204 and 216 in FIG. 4 are both transparent electrodes) can achieve the effect of the bidirectional emission light. Moreover, the substrates 102, 104, and 106 and the encapsulation layers 112, 114, and 116 are also made of light-transmitting materials.

In addition, the stacked luminescent device 100 further includes: a plurality of gold fingers 108 and a plurality of conductive lines 118. As shown in FIG. 1 and FIG. 2, the gold finger 108 is disposed on an edge of the bottom substrate 106 in the staircase region R1. In one embodiment, the gold fingers 108 may be connected to a flexible printed circuit (FPC). The conductive lines 118 may be electrically connected to or in physical contact with the electroluminescent devices EL and the gold fingers 108 along the staircase structure 150, respectively. Specifically, as shown in FIG. 3, the conductive lines 118A may be electrically connected to the gold fingers 108A from the QLED device 122 along the steps formed by the substrate 102, the encapsulation layer 114, the substrate 104, and the encapsulation layer 116. The conductive lines 118B may be electrically connected to the gold fingers 108B from the QLED device 124 along the steps formed by the substrate 104 and the encapsulation layer 116. The conductive lines 118C may be electrically connected to the gold fingers 108C from the QLED device 126 along the top surface of the bottom substrate 106. Although the conductive lines 118A and 118B may be partially suspended due to the QLED devices (e.g., 124 and 126) when extending on the staircase structure 150, they can be ignored because the thickness of the QLED devices is thin. In this case, the thicker conductive lines may be used to completely cover the staircase structure and the suspending portion, so that the gold fingers and the electroluminescent devices are electrically connected.

In the embodiment, the conductive lines 118A, 118B, 118C are electrically isolated from each other and not in contact with each other. In this case, each electroluminescent device EL may emit light independently and is not affected by the adjacent electroluminescent devices EL, thereby improving the luminous efficacy. In one embodiment, the materials of the gold fingers 108 and the conductive lines 118 may each include a conductive material, such as indium tin oxide (ITO), aluminum (Al), silver (Ag), chromium (Cr), copper (Cu), nickel (Ni), titanium (Ti), molybdenum (Mo), magnesium (Mg), platinum (Pt), gold (Au), graphite (carbon), or a combination thereof. In the embodiment, the gold fingers 108 and the conductive lines 118 may include the same conductive material or different conductive materials. For example, the gold fingers 108 are copper layers; while the conductive lines 118 are silver wires. Alternatively, both the gold fingers 108 and the conductive lines 118 are made of copper.

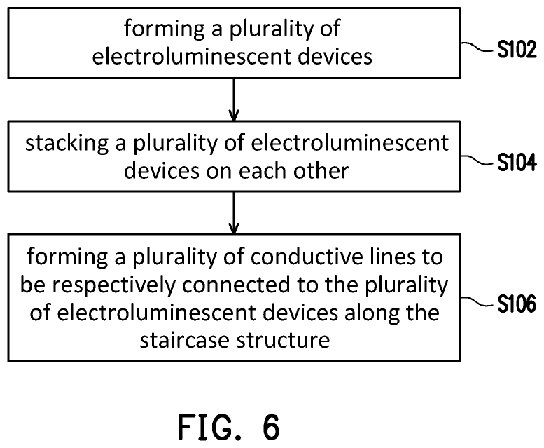

FIG. 6 is a block diagram of a method of manufacturing a stacked luminescent device according to an embodiment of the present invention.

Referring to FIG. 6, in an embodiment of the present invention, a method of manufacturing a stacked luminescent device includes following steps. First, in a step S102, a plurality of electroluminescent devices are formed. In the present embodiment, the electroluminescent devices may be formed by using a transfer printing process (e.g., flexographic printing process). The detail steps of forming the electroluminescent devices are disclosed in U.S. provisional application Ser. No. 63/143,034 and Taiwan application serial no. 110116492, the entirety of the above-mentioned patent applications is hereby incorporated by reference herein, and will not be repeated here.

Next, in a step S104, a plurality of electroluminescent devices are stacked on each other. In one embodiment, the electroluminescent devices are vertically stacked and overlapped with each other, and the related configuration is shown in FIG. 2 or FIG. 5. Specifically, after the said electroluminescent devices are formed, the electroluminescent device already has an underlying substrate and an overlying encapsulation layer. That is, as shown in FIG. 2, the first electroluminescent device 110 includes the substrate 102, the encapsulation layer 112, and the QLED device 122 sandwiched between the substrate 102 and the encapsulation layer 112; the second electroluminescent device 120 includes the substrate 104, the encapsulation layer 114 and the QLED device 124 sandwiched between the substrate 104 and the encapsulation layer 114; and the third electroluminescent device 130 includes the substrate 106, the encapsulation layer 116, and the QLED device 126 sandwiched between the substrate 106 and the encapsulation layer 116. The first electroluminescent device 110, the second electroluminescent device 120, and the third electroluminescent device 130 are stacked on each other to form a stacked luminescent device. It should be noted that the end portions of the encapsulation layers 112, 114, 116 and the end portions of the substrates 102, 104, 106 may form a staircase structure to facilitate the formation of subsequent conductive lines. In some embodiments, the electroluminescent devices may overlap completely or partially, so that the different emission lights having different colors are uniformly mixed to form a white light.

Then, in a step S106, a plurality of conductive lines are formed to be respectively connected to the electroluminescent devices along the staircase structure. In one embodiment, a method of forming the conductive lines includes: a screen printing method, a transfer printing method, an evaporation method, a conductive carbon glue sticking method, a conductive tape sticking method, or a combination thereof. It should be noted that since parts of the top surfaces of the end portions of the encapsulation layers and substrates are exposed to the staircase region, the position of the conductive lines may be exposed to facilitate to form the conductive line connecting the gold fingers and the electroluminescent devices.

Based on above, in the embodiment of the present invention, a plurality of electroluminescent devices are stacked on each other. In this case, the red quantum dot film, the green quantum dot film, and the blue quantum dot film in the electroluminescent devices are vertically stacked and overlapped with each other, so that the red emission light, the green emission light, and the blue emission light are mixed uniformly to form a white light, or the proportion of different color lights can be adjusted to generate various mixed color lights, thereby achieving the effect of colored light sheets.

In addition, the red quantum dot film, the green quantum dot film, and the blue quantum dot film in the electroluminescent devices can be formed by a transfer printing process. In such embodiment, the manufacturing method is able to achieve rapid fabrication and fabricate electroluminescent device with a large area and any shape. In this case, the method of manufacturing the stacked luminescent device of the present invention is beneficial to mass production in industry, and is able to greatly reduce production costs and increase production capacity, thereby achieving commercial utilization and enhancing commercial competitiveness.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A stacked luminescent device, comprising:
a plurality of electroluminescent devices, vertically stacked with each other to form a staircase structure on a staircase region, wherein each electroluminescent device comprises a substrate, an encapsulation layer, and a quantum dot light-emitting diode (QLED) device sandwiched between the substrate and the encapsulation layer; and
a plurality of conductive lines, respectively connected to the plurality of QLED devices in the plurality of electroluminescence devices along the staircase structure.

2. The stacked luminescent device of claim 1, wherein the plurality of electroluminescent devices comprises:
a first electroluminescent device having a red quantum dot film;
a second electroluminescent device having a green quantum dot film; and
a third electroluminescent device having a blue quantum dot film, wherein the second electroluminescent device is disposed between the first electroluminescent device and the third electroluminescent device.

3. The stacked luminescent device of claim 1, wherein each electroluminescent device has a bidirectional emission light toward above and below the electroluminescent device.

4. The stacked luminescent device of claim 1, further comprising: a plurality of gold fingers disposed on an edge of a bottommost substrate, wherein the plurality of gold fingers are respectively electrically connected to the plurality of electroluminescent devices by the plurality of conductive lines.

5. The stacked luminescent device of claim 1, wherein one of the plurality of electroluminescent devices comprises:
a first electrode layer and a second electrode layer;
a light emitting layer disposed between the first electrode layer and the second electrode layer;
a hole transport layer disposed between the first electrode layer and the light emitting layer; and
an electron transport layer disposed between the second electrode layer and the light emitting layer.

6. The stacked luminescent device of claim 5, wherein the first electrode layer comprises an anode or a cathode, the second electrode layer comprises a cathode or an anode, and the light emitting layer comprises a quantum dot layer.

7. A method of manufacturing a stacked luminescent device, comprising:
forming a plurality of electroluminescent devices by using a transfer printing process, wherein each electroluminescent device comprises a substrate, an encapsulation layer, and a quantum dot light-emitting diode (QLED) device sandwiched between the substrate and the encapsulation layer;
stacking the plurality of electroluminescent devices on each other, wherein end portions of the plurality of encapsulation layers and end portions of the plurality of substrates in the plurality of electroluminescent devices form a staircase structure; and
forming a plurality of conductive lines respectively connected to the plurality of QLED devices in the plurality of electroluminescence devices along the staircase structure.

8. The method of manufacturing the stacked luminescent device of claim 7, wherein the transfer printing process comprises a flexographic printing process.

9. The method of manufacturing the stacked luminescent device of claim 7, wherein the forming the plurality of conductive lines comprises: a screen printing method, a transfer printing method, an evaporation method, a conductive carbon glue sticking method, a conductive tape sticking method, or a combination thereof.

10. The method of manufacturing the stacked luminescent device of claim 7, wherein the plurality of electroluminescent devices comprises:
a first electroluminescent device having a red quantum dot film;
a second electroluminescent device having a green quantum dot film; and
a third electroluminescent device having a blue quantum dot film, wherein the second electroluminescent device is disposed between the first electroluminescent device and the third electroluminescent device.
